(19) United States
(12) Patent Application Publication
(10) Pub. No.: US 2004/0062056 A1
(43) Pub. Date: Apr. 1, 2004

(54) Dermatoscope

(75) Inventors: Helmut A. Heine, Herrsching (DE); Hartmut Schloesser, Poecking (DE); Dirk Schade, Penzerg (DE); Anton Schneider, Munich (DE); Otto H. Schmidt, Herrsching (DE); Wolfgang Behrendt, Andechs (DE); Norbert Merkt, Herrsching-Breitbrunn (DE)

Correspondence Address: ROTHWELL, FIGG, ERNST & MANBECK, P.C., 1425 K STREET, N.W., SUITE 800, WASHINGTON, DC, 20005, US

(73) Assignee: Heine Optotechnik GmbH & Co. KG, Herrsching (DE)

(21) Appl. No.: 10/665,615

(22) Filed: Sep. 22, 2003

(30) Foreign Application Priority Data
Sep. 26, 2002 (DE) 102 44 875.2
Feb. 28, 2003 (DE) 203 03 321.3

(51) Int. Cl. F21V 7/04; H01L 33/00

(52) U.S. Cl. 362/555

(57) ABSTRACT

In a dermatoscope having a number of light-emitting diodes (7), which are arranged around optics (6), for indirect illumination of an examination area, an optical waveguide (1) is arranged in front of each light-emitting diode (7), the light input surface of which optical waveguide (1) faces the associated light-emitting diode (7) and on whose outer wall the light which is emitted from the light-emitting diode (7) is totally reflected toward the examination area. Instead of a number of optical waveguides (1), a single conical prism is preferably provided, whose base faces the light-emitting diodes (7) and whose cone angle is designed such that the light injected into the base surface from the light-emitting diodes (7) is totally reflected on the outer cone surface.

The invention relates to a dermatoscope having a number of light-emitting diodes, which are arranged all round optics, for indirect illumination of an examination area. Dermatoscopes such as these are used for observing the skin surface and the upper skin layers in dermatology, and in other medical fields.

DE 199 38 926 A1 and DE 299 23 590 U1 disclose an optical magnification system and, respectively, an optical magnification device which can be illuminated, which have at least one light-emitting diode whose light can emerge essentially directly in the direction of the object to be observed. One disadvantage of direct illumination is that disturbing reflections occur on the surface that is to be observed.

DE 200 22 603 U1 discloses an dermatology handheld magnifying glass of this generic type, in which light-emitting diodes fitted all round magnifying glass optics emit a light beam which is directed at the object area from the inner face, which has a matt surface, of a magnifying glass container. Light is absorbed on the matt surface of the magnifying glass container, so that undesirable loss of brightness is unavoidable. Furthermore, some of the light is passed directly to the examination area, so that reflections cannot be precluded.

The invention is based on the object of providing a dermatoscope in which it is possible to illuminate the object to be observed homogeneously, without reflections and intensively.

According to the invention, this object is achieved by an optical waveguide being arranged in front of each light-emitting diode the light input surface of which optical waveguide faces the associated light-emitting diode, and on the outer surface thereof the light emitted from the light-emitting diode is totally reflected toward the examination area.

In the dermatoscope according to the invention, the light which is emitted from the light-emitting diodes, preferably high-power LEDs, is directed with virtually no losses, by means of total reflection, onto the examination area.

A particularly homogeneous distribution of the light over the examination area can be achieved by arranging a lens on the light input surface of each optical waveguide. The lenses are in the form of convergent or divergent lenses, depending on whether the light is intended to be focused onto the examination area, or is intended to be scattered.

The arrangement of a polarization filter between each of the light-emitting diodes and the optical waveguides allows the examination area to be illuminated with particularly high contrast.

For some examinations, it is necessary to illuminate the surface to be observed with directional, non-homogeneous light. To do this, shutters which can be switched selectively are arranged between one or more light-emitting diodes and the associated optical waveguides. In one alternative embodiment, the light-emitting diodes can be switched off selectively.

Some symptoms can be seen only with light at a specific wavelength, for example with UV light, or can be seen better with light at a specific wavelength. In one preferred embodiment, one or more light-emitting diodes, preferably groups at different wavelengths, are designed such that they can be switched on and off individually or in groups, for example by means of shutters or switches.

The individual optical waveguides can be combined to form groups, so that only one optical waveguide is provided for two or more light-emitting diodes. In one particularly preferred embodiment, instead of individual optical waveguides associated with the light-emitting diodes, a single conical prism is provided, whose base faces the light-emitting diodes and whose cone angle is designed such that the light which is injected into the base surface from the light-emitting diodes is totally reflected on the outer cone surface.

In this embodiment, the integral configuration of the optical waveguide or waveguides as a prism ensures particularly low-cost production and a low-cost design.

In this case, the lenses may be adhesively bonded onto or integrally formed on the base surface of the conical prism.

The conical prism preferably has an axial central hole or bore, at whose distal end, once again preferably, a transparent contact plate is arranged, covering the examination area. The surface of the central hole has preferably a rough or mat finish. This has a light scattering effect whereby a particularity good illumination is obtained of the field to be inspected.

A particularly simple embodiment of the dermatoscope is obtained by fitting, preferably integrally forming, a tubular attachment on the conical prism, which tubular attachment is used as a holder for the prism on the housing of the dermatoscope.

In a further preferred embodiment, holes into which the light-emitting diodes project are provided in the base surface of the conical prism. This allows the examination area to be illuminated with particularly little reflection, since no parasitic light can reach the examination area directly.

In order to document the examinations carried out using the dermatoscope, the proximal end, that is to say the end opposite the contact plate, of the housing, is in one preferred embodiment designed such that a camera can be plugged onto the housing via an adapter, to be precise such that the previously adjusted optics are no longer misadjusted even if the housing is rotated with respect to the camera. Independently of the dermatoscope according to the invention, this embodiment is also suitable for other optical examination appliances, for example opthalmoscopes, otoscopes, etc., which have a suitable housing for this purpose and in which the examination result is intended to be documented.

The dermatoscope according to the invention is, of course, also suitable for observing other surfaces or any surfaces, for example for material testing.

Embodiments of the dermatoscope according to the invention will be explained in the following text. In the figures:

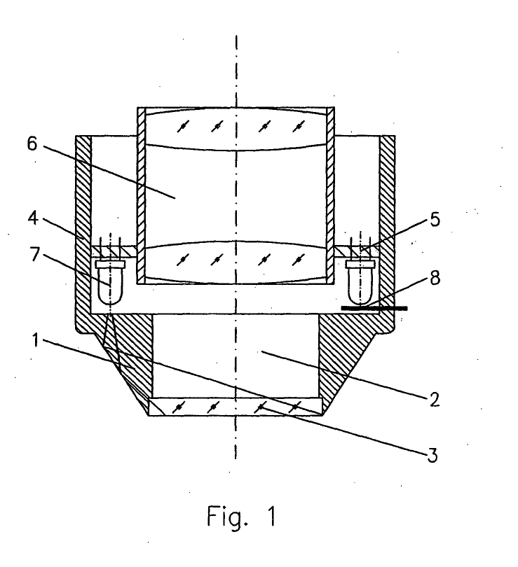

FIG. 1 shows the cross section through an end piece of a first embodiment of the dermatoscope according to the invention with a shutter,

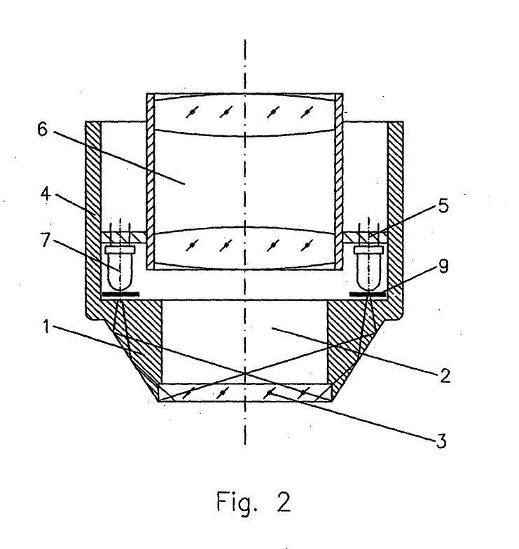

FIG. 2 shows the cross section through the end piece of a second embodiment of the dermatoscope according to the invention with a polarization filter,

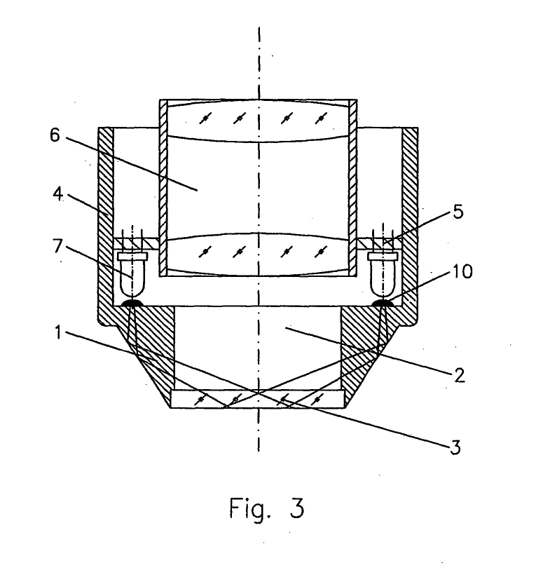

FIG. 3 shows the cross section through the end piece of a third embodiment of the dermatoscope according to the invention with lenses fitted to the base surface of the conical prism,

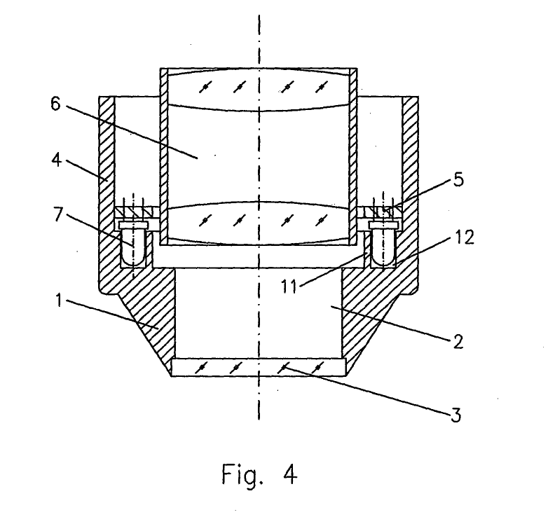

FIG. 4 shows the cross section through the end piece of a fourth embodiment of the dermatoscope according to the invention with light-emitting diodes recessed in holes,

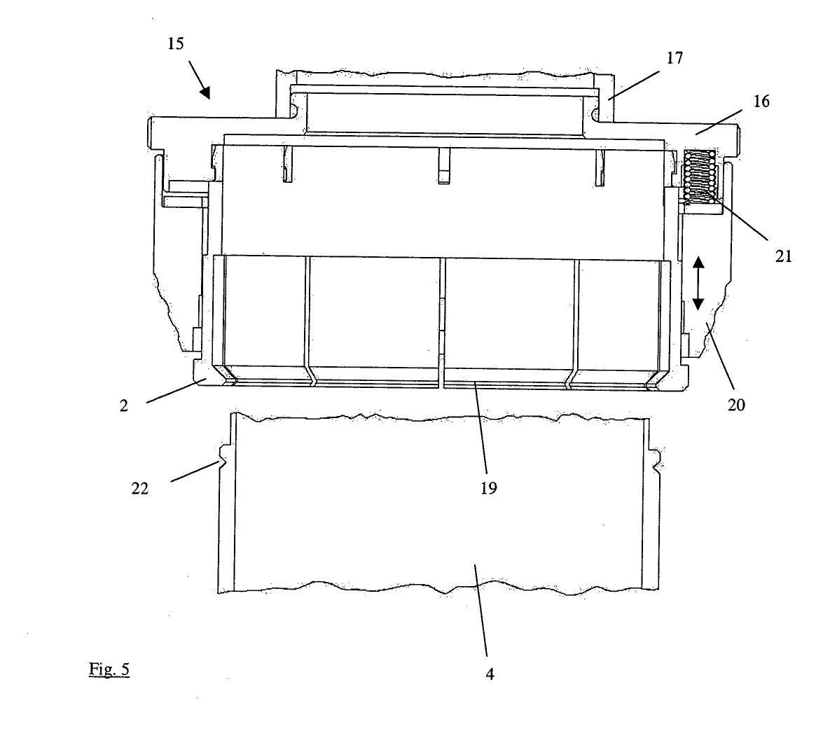

FIG. 5 shows the cross section through an adapter for connecting the dermatoscope to a camera in the open state, and

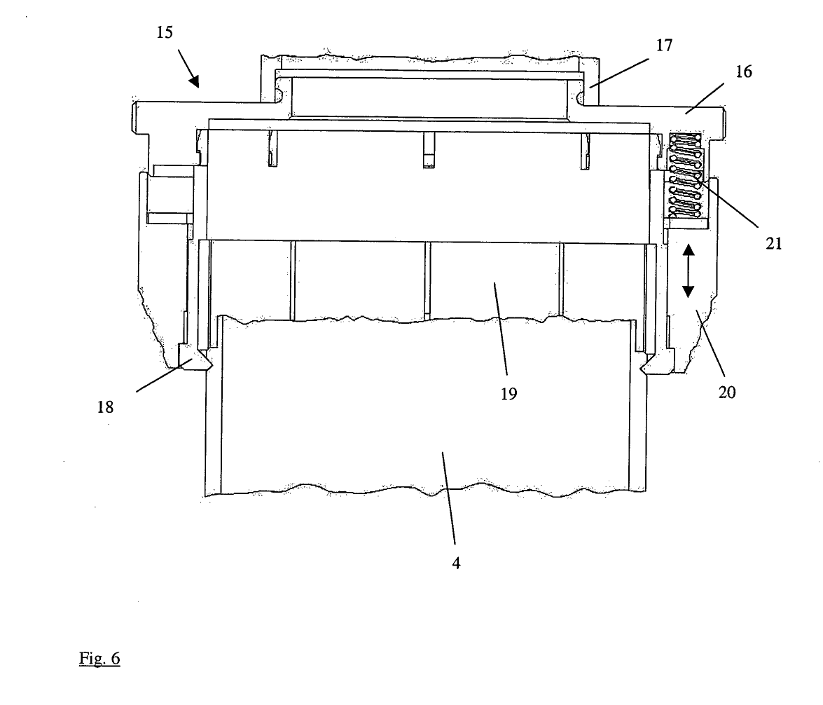

FIG. 6 shows the cross section through the adapter in FIG. 5, in the closed state.

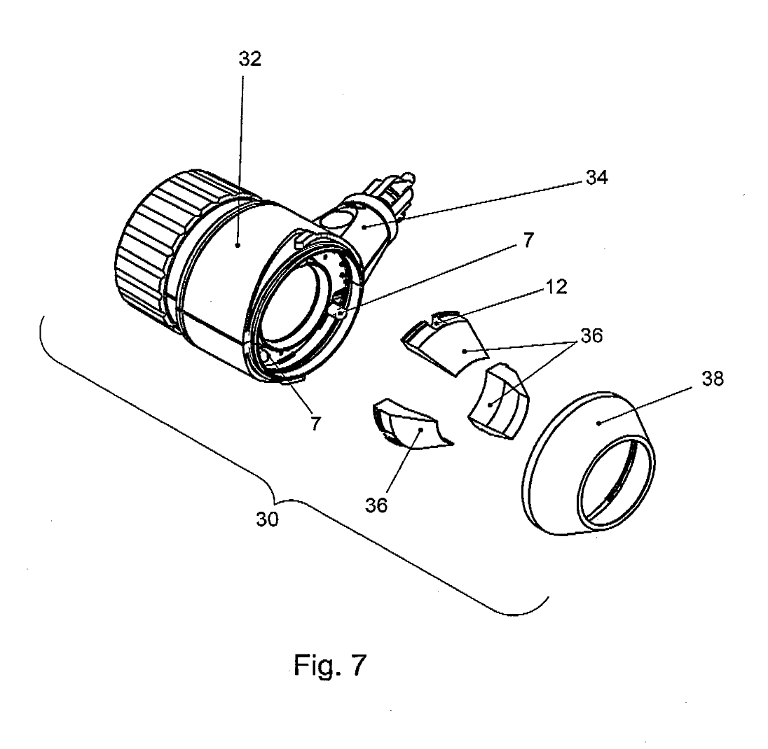

FIG. 7 shows an exploded view of a fifth embodiment of the dermatoscope according to the invention.

FIG. 1 shows, as the optical waveguide 1, a conical prism with a central hole 2, to whose end facing the examination area a contact plate 3 is attached, which is composed of glass or transparent plastic. A tubular attachment 4 is integrally formed on the outer edge of the base surface of the conical prism and is part of a housing (not shown) or can be pushed onto a housing (likewise not shown) and reinforces the housing mechanically.

The tubular attachment 4 is fitted with a printed circuit board 5 with light-emitting diodes 7 arranged all round optics 6. The optics 6 are mounted rigidly, or such that they can move in the axial direction, in the housing (which is not shown).

As shown in the left-hand half of FIG. 1, the light which is emitted from the light-emitting diodes 7 enters the base surface of the prism, is totally reflected on the outer wall of the prism, and is emitted from there onto the contact plate 3 and onto the examination area located underneath it. The light flux is thus transmitted without any losses onto the surface to be illuminated.

As shown in the illustration on the right-hand side of FIG. 1, one or more light-emitting diodes 7 may be blanked out by means of in each case one slide or shutter 8, so that contrasts are produced by shadowing on the surface to be observed. Alternatively, it may be possible to switch off one or more of the light-emitting diodes.

The illustration in FIG. 2 corresponds to that in FIG. 1. In this case, a polarization filter 9 is arranged between the light-emitting diodes 7 and the base surface of the conical prism 1.

In the embodiment in FIG. 3, lenses 10 are adhesively bonded onto or are integrally formed on the base surface of the conical prism 1, and focus or scatter the light emitted from the light-emitting diodes 7 onto the examination area. Instead of individual lenses 10, a continuous lens ring may be fitted onto the base surface of the prismatic optical waveguide 1.

The embodiments in FIGS. 1 to 3 may, of course, be combined with one another in any desired manner.

FIG. 4 shows an embodiment in which a cylindrical ring 11 is fitted, in this case being integrally formed, adjacent to the base surface of the conical prism 1 and the tubular attachment 4. A hole 12 into which the light-emitting diodes 7 project is provided for each light-emitting diode 7 in the ring 11. In this embodiment, the light-emitting diodes 7 are surrounded by the material of the ring 11, so that no parasitic light can reach the examination area directly from the light-emitting diodes 7. In order to keep all the parasitic light completely away from the examination area the corresponding surface of the prism 1 or of the ring 11 could be blackened.

As in the embodiments in FIGS. 1 to 3, shutters, polarization filters and lenses can likewise be arranged at the bottom of the holes 12.

FIGS. 5 and 6 show the cross section through an adapter 15 in the open position and in the closed position, respectively. The adapter 15 has a camera ring 16, which is mounted on a camera objective 17, for example being screwed to it. On the side opposite the objective 17, the adapter 15 has an annular spacer 18, with a row of spring elements 19 on its side facing away from the camera ring 16. The spacer 18 is surrounded by an outer ring 20 which can move in the axial direction and is supported via spring elements, for example compression springs 21, against the camera ring 16. Underneath the adapter 15 in FIGS. 5 and 6, the (correspondingly extended) attachment 4 on a dermatoscope is shown with a wedge-shaped annular groove 22.

When the moving outer ring 20 is moved by hand in the direction of the camera (FIG. 5), then it spreads the spring elements 19 outward, and the attachment 4 can be inserted into the opening in the spacer 18. When the outer ring 20 is released again (FIG. 6), then corresponding tabs on the spring elements 19 engage in the annular groove 22, so that the adapter 15 and the dermatoscope are connected to one another in an inter-locked manner. Rotation of the dermatoscope housing with respect to the adapter 15 has no influence on the position of the optics of the dermatoscope. This embodiment of the adapter 15 has the advantage that it can be operated by just one hand, and it is impossible to inadvertently release the connection in a simple manner.

FIG. 7, finally, shows an exploded outer view of a dermatoscope 30 with a usual housing 32 and light entrance structure 34. The unitary optical wave guide 1 of FIG. 1, having the form of a conical prism, is replaced by a number of separate, individual light guides 36, one for each light emitting-emitting diode 7. In the embodiment here shown the total number of individual light guides 7 is three corresponding to the total number of light-emitting diodes 7. Of course, other numbers of light-emitting diodes 7 and individual light guides may be chosen. The individual light guides 36 each forming a sector of a conical prism so that, when put together and held by a conical cover 38, they again have the form of a conical prism. The structure of FIG. 7 may be combined with lenses, polarization filters, shutters, switches and diodes emitting light of different wave lengths the same way as described above with reference to FIGS. 1 to 4.

1. A dermatoscope comprising a plurality of light-emitting diodes, which are arranged around optics, for indirect illumination of an examination area, and a plurality of optical waveguides, each of said optical wave guides being arranged in front of one associated light-emitting diode and having a light input surface which faces said associated light-emitting diode, said optical waveguides having an outer wall totally reflecting light emitted from said associated light-emitting diode toward said examination area.

2. The dermatoscope as claimed in claim 1, wherein a lens is arranged on said light input surface of each of said optical waveguides.

3. The dermatoscope as claimed in claim 1, wherein a polarization filter is arranged between each of said light-emitting diodes and said optical waveguides.

4. The dermatoscope as claimed in claim 1, wherein selectively switchable shutters are arranged between said light-emitting diodes and said optical waveguides.

5. The dermatoscope as claimed in of claim 1, wherein said light-emitting diodes can be switched off selectively.

6. The dermatoscope as claimed in of claim 1, wherein said light-emitting diodes emit light at a different wavelength individually or in groups, and can be switched on and off individually or in groups.

7. A dermatoscope comprising a plurality of light-emitting diodes, which are arranged around optics, for indirect illumination of an examination area, and a single conical prism having a basis surface facing said light-emitting diodes, the cone angle of said conical prism being designed such that the light which is injected into said basis surface from said light-emitting diodes is totally reflected on an outer cone surface of said conical prism.

8. The dermatoscope as claimed in claim 7, wherein lenses is provided on said basis surface, each of said lenses being arranged opposite to an associated light-emitting diode.

9. The dermatoscope as claimed in claim 8, wherein said lenses are adhesively bonded onto or are integrally formed with said base surface of said conical prism.

10. The dermatoscope as claimed in claim 7, wherein a polarization filter is arranged between each of said light-emitting diodes and said conical prism.

11. The dermatoscope as claimed in claim 7, wherein selectively switchable shutters are arranged between said light-emitting diodes and said conical prism.

12. The dermatoscope as claimed in of claim 7, wherein said light-emitting diodes can be switched off selectively.

13. The dermatoscope as claimed in of claim 7, wherein said light-emitting diodes emit light at a different wavelength individually or in groups, and can be switched on and off individually or in groups.

14. The dermatoscope as claimed in claim 7 , wherein said conical prism has an axial central hole.

15. The dermatoscope as claimed in claim 14, wherein said central hole comprises a surface having a mat finish.

16. The dermatoscope as claimed in claim 14, wherein a transparent contact plate covering said examination area, is arranged at an distal end of said central hole.

17. The dermatoscope as claimed in claim 7, wherein a tubular attachment fitted on said conical prism represents one part of a housing or is used as a holder for said prism on a housing of said dermatoscope for reinforcing.

18. The dermatoscope as claimed in claim 7, wherein holes into which said light-emitting diodes project are provided in said base surface of said conical prism or in a ring adjacent to said base surface.

19. The dermatoscope as claimed in claim 17, wherein a proximal end of said housing is designed such that a camera or additional optics can be plugged onto said housing via an adapter.

20. The dermatoscope as claimed in claim 17, wherein said housing is coupled to a camera such that previously adjusted optics cannot be misadjusted even if said housing is rotated with respect to said camera or with respect to additional optics.

21. The dermatoscope as claimed in claim 19, wherein said adapter comprises a camera ring which can be mounted on optics of said camera, a spacer with a series of spring elements arranged in the form of a ring, and a slide ring which surrounds the spacer, releases said spring elements in an open position and provides an interlocking connection to said dermatoscope housing in a closed position.
